(19) United States
(12) Patent Application Publication
(10) Pub. No.: US 2020/0383212 A1
(43) Pub. Date: Dec. 3, 2020

(54) SERVER AND PRINTED CIRCUIT BOARD PRINTING METHOD

(71) Applicant: HONGFUJIN PRECISION ELECTRONICS(TIANJIN)CO.,LTD., Tianjin (CN)

(72) Inventors: YAO-HUA GONG, Tianjin (CN); MING-KUEI LIAO, Singapore (SG)

(21) Appl. No.: 16/509,603

(22) Filed: Jul. 12, 2019

(30) Foreign Application Priority Data
May 31, 2019 (CN) 201910473168.7

(51) Int. Cl. H05K 3/20; H05K 3/00; G06F 17/50

(52) U.S. Cl. CPC H05K 3/207; H05K 3/0005; H05K 2203/0195; H05K 2203/0126; G06F 17/5068

(57) ABSTRACT

A printed circuit board (PCB) printing method includes obtaining PCB parameters and stencil printing parameters of a PCB to be printed, determining print parameters for printing the PCB according to a print model parameter relationship, the obtained PCB parameters, and standard values of solder paste detection parameters, transmitting the determined print parameters to a printer for printing the PCB, receiving values of the solder paste detection parameters detected by a solder paste inspection device, determining whether the detected values are within a preset range of the standard values, and re-determining the print parameters when the detected values are not within the preset range of the standard values. The print model parameter relationship indicates a relationship of the PCB parameters and the print parameters to solder paste detection parameters. The solder paste detection parameters include information related to solder paste on the printed PCB.

### FIELD

The subject matter herein generally relates to printed circuit boards, and more particularly to a server and a printed circuit board printing method implemented by the server.

### BACKGROUND

Generally, printed circuit boards (PCBs) are printed by a printer according to print parameters manually set on the printer. The print parameters are manually set according to experience of an operator. Therefore, solder paste printed on the PCB may not be optimal.

### BRIEF DESCRIPTION OF THE DRAWINGS

Implementations of the present disclosure will now be described, by way of embodiments, with reference to the attached figures.

FIG. 1 is a schematic block diagram of an embodiment of a server.

FIG. 2 is a flowchart of an embodiment of a printed circuit board printing method.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series and the like.

In general, the word “module” as used hereinafter refers to logic embodied in hardware or firmware, or to a collection of software instructions, written in a programming language such as, for example, Java, C, or assembly. One or more software instructions in the modules may be embedded in firmware such as in an erasable-programmable read-only memory (EPROM). It will be appreciated that the modules may comprise connected logic units, such as gates and flip-flops, and may comprise programmable units, such as programmable gate arrays or processors. The modules described herein may be implemented as either software and/or hardware modules and may be stored in any type of computer-readable medium or other computer storage device.

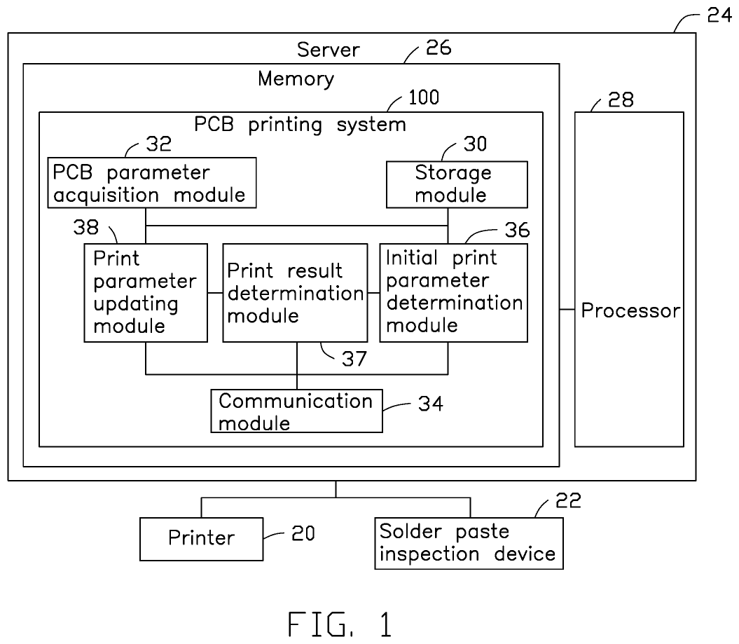

FIG. 1 shows an embodiment of a printed circuit board (PCB) printing system 100. The PCB printing system 100 is applied in a server 24, which is communicatively coupled to a printed circuit board (PCB) printer 20 (hereinafter “the printer 20”) and a solder paste inspection device 22. The PCB printing system 100 automatically determines print parameters of a PCB, such that the printer 20 prints a PCB in accordance with the automatically determined print parameters.

The PCB printing system 100 includes a storage module 30, a PCB parameter acquisition module 32, a communication module 34, an initial print parameter determination module 36, a print result determination module 37, and a print parameter updating module 38. The server 24 includes a memory 26 and a processor 28. The memory 26 stores the PCB printing system 100, and the processor 28 executes the PCB printing system 100.

The storage module 30 stores a print model parameter relationship. The print model parameter relationship indicates a relationship of PCB parameters and print parameters to solder paste detection parameters. The PCB parameters include information such as a board length (L), a board width (W), and a board thickness (T) of the PCB. The print parameters include information such as a blade pressure (pres), a printing speed (spd), a de-molding speed (sepa_spd), and a mold release distance (sepa_dist) at a time of printing. The solder paste detection parameters include information related to solder paste on the printed PCB, such as a solder paste height (real_height), a height expansion and contraction coefficient (transf_height), a solder paste area (real_area), an area expansion and contraction coefficient (transf_area), a solder paste volume (real_volumn), a volume expansion and contraction coefficient (transf_volumn), and other parameters. The print model parameter relationship is obtained by analyzing and modeling print data of a plurality of printed PCBs. The relationship of each solder paste detection parameter in the print model parameter relationship to the PCB parameters and the print parameters is similar. Each solder paste detection parameter is calculated by a linear sum of the PCB parameters and the print parameters.

For example, the area expansion and contraction coefficient (transf_area) is calculated according to the following equation:

Transf_area=b0+b1L+b2W+b3T+b4pres+b5spd+b6sepa_spd+b7sepa_dist

In the above equation, b0, b1, b2, b3, b4, b5, b6, and b7 are linear parameters obtained by analyzing the print data of the plurality of printed PCBs.

The PCB parameter acquisition module 32 obtains the PCB parameters of a PCB to be printed by the printer 20 to determine stencil printing parameters corresponding to the PCB. The stencil printing parameters include information such as a hole length, a hole width, and a hole thickness of an opening of holes in a stencil design of the PCB. In one embodiment, the server 24 includes a display screen and stores a PCB parameters table. The PCB parameters table includes identification codes of different kinds of PCBs and PCB parameters and stencil printing parameters corresponding to the identification codes. The identification code of the PCB may be an item number of the PCB. The display screen displays an input interface for a user to input the identification code of the PCB. The PCB parameter acquisition module 32 automatically acquires the corresponding PCB parameters and the corresponding stencil printing parameters from the PCB parameters table according to the input identification code of the PCB. In other embodiments, the PCB parameters table is stored in a terminal communicatively coupled to the server 24. In other embodiments, the server 24 is communicatively coupled to a scanner. The scanner scans the PCB before the PCB enters the printer 20 to obtain the identification code of the PCB and transmits the identification code of the PCB to the server 24, and the PCB parameter acquisition module 32 automatically acquires the corresponding PCB parameters and the corresponding stencil printing parameters from the PCB parameters table according to the identification code of the PCB transmitted by the scanner.

The initial print parameter determination module 36 determines the print parameters for printing the PCB according to the print model parameter relationship, the obtained PCB parameters, and standard values of the solder paste detection parameters. The standard values of the solder paste detection parameters are desired values of preset solder paste detection parameters. In one embodiment, the standard values of the solder paste detection parameters may be stored in the storage module 30. In another embodiment, the standard values of the solder paste detection parameters can be input through an input interface of the display screen.

The communication module 34 controls a communication device (such as a fiber optic connection port) of the server 24 to communicate with the printer 20 and the solder paste inspection device 22 and transmit the determined print parameters to the printer 20. The printer 20 sets the print parameters of the PCB and prints the PCB according to the print parameters transmitted by the server 24. The solder paste inspection device 22 performs solder paste inspection on the printed PCB to obtain the detected values of the solder paste detection parameters and transmits the detected values of the solder paste detection parameters to the server 24. In a printing process, due to some factors of the printer 20, although the print parameters are determined according to the standard values of the solder paste detection parameters, the solder paste of the actual printed PCB may not match the standard values.

The print result determination module 37 determines whether the detected values of the solder paste detection parameters are within a preset range of the standard values of the solder paste detection parameters. The preset range may be an interval between an upper limit percentage and a lower limit percentage.

When the detected values of the solder paste detection parameters are not within the preset range of the standard values, the print parameter updating module 38 re-determines the print parameters according to the detected values, the PCB parameters, and the print model parameter relationship, and transmits the updated print parameters to the printer 20 for updating the print parameters in real time, so that a next PCB is printed based on the updated print parameters. Since the PCBs having the same item number are printed together, the print parameters are dynamically updated according to the detected values from the print result determination module 37, so that the printer 20 updates the print parameters in real time to improve a PCB print quality and yield.

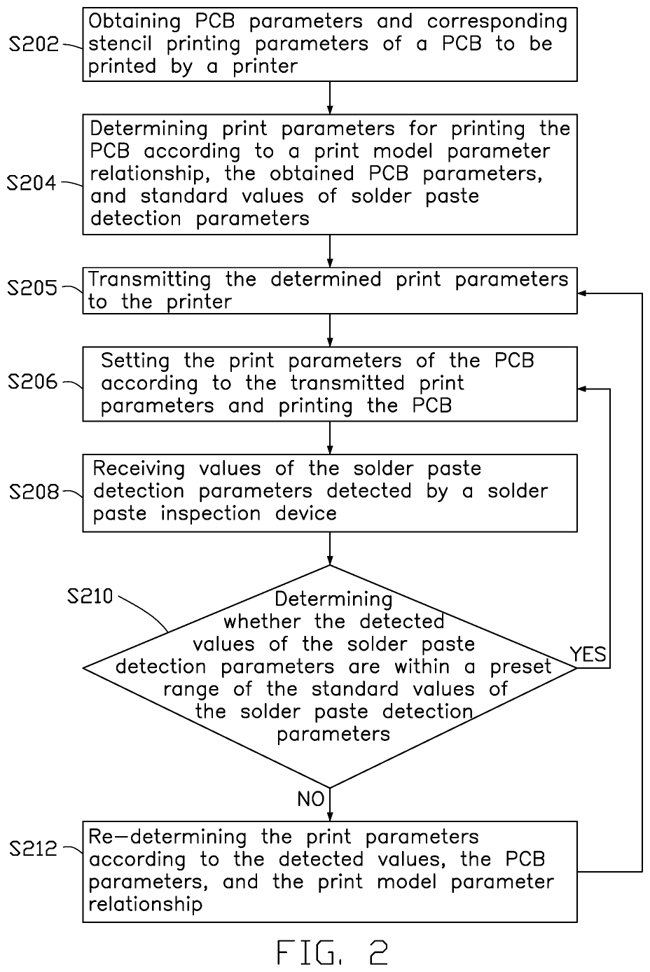

FIG. 2 shows a flowchart of a printed circuit board (PCB) printing method. The method is provided by way of embodiment, as there are a variety of ways to carry out the method. The method described below can be carried out using the configurations illustrated in FIG. 1, for example, and various elements of these figures are referenced in explaining the example method. Each block shown in FIG. 2 represents one or more processes, methods, or subroutines carried out in the example method. Furthermore, the illustrated order of blocks is by example only, and the order of the blocks can be changed. Additional blocks can be added or fewer blocks can be utilized, without departing from this disclosure.

At block S202, PCB parameters of a PCB to be printed by the printer 20 and stencil printing parameters corresponding to the PCB are obtained.

In one embodiment, the server 24 obtains the PCB parameters and the stencil printing parameters according to the identification code of the PCB and the PCB parameters table input to the server 24. The PCB parameters table includes an identification code of each kind of PCB and the corresponding PCB parameters and the corresponding stencil printing parameters. The identification code of the PCB may be the item number of the PCB. The PCB parameters table is stored in the server 24 or in a terminal communicatively coupled to the server 24. In other embodiments, the server 24 automatically acquires the PCB parameters and the corresponding stencil printing parameters according to the identification code of the PCB and the PCB parameters table transmitted by a scanner coupled to the server 24. The PCB parameters of the PCB includes information such as a board length, a board width and a board thickness of the PCB. The stencil printing parameters include information such as a hole length, a hole width, and a hole thickness of an opening of holes in a stencil design of the PCB.

At block S204, print parameters for printing the PCB are determined according to the print model parameter relationship, the obtained PCB parameters, and standard values of the solder paste detection parameters. The print model parameter relationship indicates a relationship of PCB parameters and print parameters to solder paste detection parameters. The print parameters include information such as a blade pressure (pres), a printing speed (spd), a de-molding speed (sepa_spd), and a mold release distance (sepa_dist) at a time of printing. The solder paste detection parameters include information related to solder paste on the printed PCB, such as a solder paste height (real_height), a height expansion and contraction coefficient (transf_height), a solder paste area (real_area), an area expansion and contraction coefficient (transf_area), a solder paste volume (real_volumn), a volume expansion and contraction coefficient (transf_volumn), and other parameters. The print model parameter relationship is obtained by analyzing and modeling print data of a plurality of printed PCBs.

At block S205, the determined print parameters are transmitted to the printer 20.

At block S206, the printer 20 sets the print parameters of the PCB according to the transmitted print parameters and prints the PCB.

At block S208, values of the solder paste detection parameters detected by the solder paste inspection device 22 are received.

At block S210, whether the detected values of the solder paste detection parameters are within a preset range of the standard values of the solder paste detection parameters is determined. When the detected values of the solder paste detection parameters are within the preset range of the standard values, block S206 is implemented. When the detected values of the solder paste detection parameters are not within the preset range of the standard values, block S212 is implemented.

At block S212, the print parameters are re-determined according to the detected values, the PCB parameters, and the print model parameter relationship.

Block S205 and the subsequent blocks may be implemented after block S212 until the PCBs are finished printing.

The PCB printing system 100 and the PCB printing method automatically determine the print parameters according to the PCB parameters and the detected values of the solder paste detection parameters and print the PCBs according to the automatically determined print parameters, thereby improving the quality and yield of PCB printing.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A server communicatively coupled to a printed circuit board (PCB) printer and a solder paste inspection device, the server comprising:
a processor; and
a memory storing a plurality of instructions, which when executed by the processor, cause the processor to:
store a print model parameter relationship, the print model parameter relationship indicating a relationship of PCB parameters and print parameters to solder paste detection parameters, the solder paste detection parameters comprising information related to solder paste on the printed PCB;
obtain PCB parameters and stencil printing parameters for printing a PCB;
determine the print parameters for printing the PCB according to the print model parameter relationship, the obtained PCB parameters, and standard values of the solder paste detection parameters;
transmit the determined print parameters to the printer for setting and printing the PCB, and receiving values of the solder paste detection parameters detected by the solder paste inspection device;
determine whether the detected values of the solder paste detection parameters are within a preset range of the standard values of the solder paste detection parameters; and
re-determines the print parameters according to the detected values, the PCB parameters, and the print model parameter relationship when the detected values of the solder paste detection parameters are not within the preset range of the standard values.

2. The server of claim 1, wherein:
the memory stores a PCB parameters table comprising identification codes of different kinds of PCBs and the PCB parameters and the stencil printing parameters corresponding to the identification codes.

3. The server of claim 2, wherein:
the processor automatically acquires the corresponding PCB parameters and the corresponding stencil printing parameters from a PCB parameters table according to an identification code of the PCB input to the server.

4. The server of claim 2, wherein:
the processor automatically acquires the corresponding PCB parameters and the corresponding stencil printing parameters from the PCB parameters table according to an identification code of the PCB transmitted by a scanner.

5. The server of claim 2, wherein:
the identification code of the PCB is an item number of the PCB.

6. The server of claim 1, wherein:
the solder paste detection parameters comprise a solder paste height, a height expansion and contraction coefficient, a solder paste area, an area expansion and contraction coefficient, a solder paste volume, and a volume expansion and contraction coefficient.

7. The server of claim 1, wherein:
the PCB parameters comprise a board length, a board width, and a board thickness of the PCB.

8. The server of claim 1, wherein:
the stencil printing parameters comprise a hole length, a hole width, and a hole thickness of an opening of holes in a stencil design of the PCB.

9. A printed circuit board (PCB) printing method comprising:
obtaining PCB parameters of a PCB to be printed and stencil printing parameters corresponding to the PCB;
determining print parameters for printing the PCB according to a print model parameter relationship, the obtained PCB parameters, and standard values of solder paste detection parameters, the print model parameter relationship indicating a relationship of the PCB parameters and the print parameters to solder paste detection parameters, the solder paste detection parameters comprising information related to solder paste on the printed PCB;
transmitting the determined print parameters to a printer for setting and printing the PCB;
receiving values of the solder paste detection parameters detected by a solder paste inspection device;
determining whether the detected values of the solder paste detection parameters are within a preset range of the standard values of the solder paste detection parameters; and
re-determining the print parameters according to the detected values, the PCB parameters, and the print model parameter relationship when the detected values of the solder paste detection parameters are not within the preset range of the standard values.

10. The PCB printing method of claim 9, wherein;
the PCB parameters and the stencil printing parameters correspond to identification codes of different kinds of PCBs in a PCB parameters table.

11. The PCB printing method of claim 10, wherein:
the corresponding PCB parameters and the corresponding stencil printing parameters are automatically acquired from the PCB parameters table according to the identification code of the PCB.

12. The PCB printing method of claim 10, wherein:
the corresponding PCB parameters and the corresponding stencil printing parameters are automatically acquired from the PCB parameters table according to the identification code of the PCB transmitted by a scanner.

13. The PCB printing method of claim 9, wherein:
the solder paste detection parameters comprise a solder paste height, a height expansion and contraction coefficient, a solder paste area, an area expansion and contraction coefficient, a solder paste volume, and a volume expansion and contraction coefficient.

14. The PCB printing method of claim 9, wherein:
the PCB parameters comprise a board length, a board width, and a board thickness of the PCB.

15. The PCB printing method of claim 9, wherein:
the stencil printing parameters comprise a hole length, a hole width, and a hole thickness of an opening of holes in a stencil design of the PCB.
